(19) United States
(12) Patent Application Publication
(10) Pub. No.: US 2025/0038770 A1
(43) Pub. Date: Jan. 30, 2025

(54) Processing a Data Word

(71) Applicant: Infineon Technologies AG, Neubiberg (DE)

(72) Inventors: Bernd Meyer, München (DE); Berndt Gammel, Markt-Schwaben (DE); Rainer Göttfert, Putzbrunn (DE)

(21) Appl. No.: 18/779,803

(22) Filed: Jul. 22, 2024

(30) Foreign Application Priority Data
Jul. 25, 2023 (DE) 102023119646.4

(51) Int. Cl. H03M 13/15

(52) U.S. Cl. CPC H03M 13/1575

(57) ABSTRACT

An approach for processing a data word in which a data word is received, in which a first syndrome of a first code is determined, the first syndrome having components, and in which a second syndrome of a second code is determined when the syndrome of the first code recognizes an error, the second syndrome comprising the components of the first syndrome.

### TECHNICAL FIELD

The invention relates to processing a data word, in particular recognizing and/or correcting an error in the data word.

### BACKGROUND

By way of example, the data word is determined by a predefined set of bits that are read from a memory. The bits can comprise data bits and/or redundancy bits, the redundancy bits being able to be used for error correction.

### SUMMARY

The object of the invention is to improve known approaches to error recognition and/or error correction in terms of performance or energy consumption, for example.

This object is achieved in accordance with the features of the independent claims.

In order to achieve the object, a method for processing a data word is proposed
in which a data word is received,
in which a first syndrome of a first code is determined, the first syndrome having components,
in which a second syndrome of a second code is determined when the syndrome of the first code recognizes an error, the second syndrome comprising the components of the first syndrome.

The components of the syndrome may also be referred to as syndrome components.

An advantage in this case is that the syndrome computation for the received data words is carried out not in full, but rather only in part, i.e. within the scope of the first syndrome. As most data words are generally error-free, this allows clear savings in terms of time, computing power and energy to be achieved.

The term ‘code’ here is geared to an error code that is capable of correcting at least one error and of recognizing at least two errors. The code is defined by a matrix H (parity check matrix). The code has the length n, the dimension k=n−r and the minimum distance d and has 2^{k} different codewords.

The first code is contained in the second code, i.e. the parity check matrix of the second code also comprises the parity check matrix of the first code.

One development is that the received data word is recognized as error-free if no errors were recognized on the basis of the first syndrome of the first code.

One development is that if an error was recognized on the basis of the first syndrome of the first code, this error is corrected by means of the second code.

One development is that the first code can recognize at least t bit errors and the second code can correct t bit errors.

One development is that the first code has a minimum distance of t+1.

One development is that the first code and/or the second code is a linear code.

One development is that the data word has data bits or data bits and redundancy bits.

One development is that if an error was recognized on the basis of the first syndrome of the first code, this error is corrected by means of the second code only in the data bits.

A method for processing a data word is also proposed
in which a data word is received,
in which a first syndrome of a first code is determined,
in which a syndrome of another code is determined when the syndrome of the first code recognizes an error, and an error correction is carried out on the basis of the syndrome of the other code, or,
if error correction on the basis of the other code is not possible, a second syndrome of a second code is determined,
wherein the other code is contained in the second code, and the first code is contained in the other code.

One option is that the second code “contains” a multiplicity of codes, i.e. there are multiple other codes between the first and second codes, each of which renders part of the error correction on the basis of a progressively increasing number of syndrome components (also referred to as syndrome coordinates). This is consistent with a gradual escalation of the error correction: An increasing number of syndrome components is computed from the (first) other code onward and this is taken as a basis for attempting to carry out an error correction. If this is successful, the error correction can be terminated with fewer than the syndrome components necessary for the second code. As each other code is contained in the second code, the second code comprises all syndrome components. In principle, it holds that:

Anz(s_{C})>Anz(s_{Cp})>. . . >Anz(s_{C2})>Anz(s_{C1}),

where Anz (s_{Y}) indicates the number of syndrome components of the syndrome s for the code Y.

The code C₁ is contained in the code C₂, etc. All codes Cᵢ(with i=1, . . . , p) are contained in the code Cᵢ₊₁ (if present) and also in the second code C.

Thus (only) the last stage of the error correction is the computation of all syndrome components of the second code C. It advantageously occurs only when error correction was previously not possible with parts of the syndrome components.

One development is that if an error that cannot be corrected on the basis of the other code was recognized on the basis of the other syndrome of the other code, this error is corrected by means of the second code.

A device for processing a data word is also specified that is configured to carry out the steps of the method described herein.

To this end, the device can comprise a processing unit, in particular a processor unit and/or an at least partly hardwired or logic circuit arrangement, which is configured for example such that the method as described herein is able to be carried out. This can involve there being provision for any type of processor or computer with appropriately required peripherals (memory, input/output interfaces, input/output devices, etc.). The above explanations relating to the method apply mutatis mutandis to the device. The respective device may be embodied in one component or in a manner distributed over multiple components.

Furthermore, a computer program product is specified that is directly loadable into a memory of a digital computer and comprises program code parts that can be used to carry out the steps of the method described herein.

Furthermore, the aforementioned problem is solved by means of a computer-readable storage medium, e.g. any memory, comprising instructions (e.g. in the form of program code) executable by a computer that are suitable for the computer to carry out steps of the method described here.

The above-described properties, features and advantages and the way in which they are achieved will be explained further in association with the following schematic description of exemplary embodiments which are explained in greater detail in association with the drawings. In this case, identical or identically acting elements may be provided with identical reference signs, for the sake of clarity.

### BRIEF DESCRIPTION OF THE FIGURES

FIG. 1 shows a parity check matrix H, a region of this parity check matrix determining a parity check matrix H1′.

FIG. 2 shows an illustrative parity check matrix H3 with a region marked by dashed lines that is referred to as the submatrix of the parity check matrix H3.

FIG. 3 shows an illustrative parity check matrix H5 with two submatrices.

FIG. 4 shows an illustrative parity check matrix H6 of a systematic linear (15, 4, 8) code C and three submatrices.

FIG. 5 shows a schematic diagram of escalated syndrome computations according to example 5.

FIG. 6 shows an illustrative flowchart for a reduced syndrome computation.

### DETAILED DESCRIPTION

### Introduction, Terms

The following notations are used: GF(2)={0, 1} is the second-order finite body, GF(2)ⁿ is the n-dimensional vector space of all binary row vectors of length n and C^{T} is the transposed vector for a vector c. The abbreviation GF denotes the Galois field.

H is a binary r×n matrix, i.e. a matrix containing entries comprising zeros and ones, that has r rows and n columns. If the r rows of the matrix H are linearly independent of one another as vectors of the vector space V=GF(2)ⁿ, the matrix H has the rank r.

The matrix H defines a linear code C of length n and dimension k=n−r. The code C is the null space of the matrix H, i.e.

C={c∈GF(2)n:HcT=0}.

The matrix H is called the parity check matrix of the code C. The code C is clearly defined by the parity check matrix H. However, this does not apply in reverse: A code C has multiple (mutually equivalent) parity check matrices.

The code C is a k-dimensional linear subspace of the n-dimensional GF(2) vector space V=GF(2)ⁿ. The code C therefore contains precisely 2^{k} different vectors referred to as codewords of the code C. Each linear code contains the zero vector 0 as one of its codewords.

The number of ones in a vector v comprising V=GF(2)ⁿ is called the Hamming weight w(v) of the vector v. The minimum distance d of a code C is the smallest occurring Hamming weight among all non-0 codewords:

$$d = min \{ w ( c ) : c ∈ C with c \neq 0 \} .$$

For a linear code with the minimum distance d, two different codewords differ in at least d coordinates. This is the basis for the ability of a code to recognize and/or correct a specific number of bit errors (which can arise during data transmission or data storage, for example).

A code with the minimum distance d can recognize all t-bit errors, with 1≤t≤d−1, and can correct all e-bit errors, with 1≤e<d/2.

A code can accordingly recognize at least twice as many bit errors as it can correct. If for example the minimum distance is d=5, all 1-bit errors and 2-bit errors can be corrected and all 1-bit errors, 2-bit errors, 3-bit errors and 4-bit errors can be recognized. Accordingly, for a minimum distance of d=4, all 1-bit errors can be corrected and all 1-bit errors, 2-bit errors and 3-bit errors can be recognized.

A central element for error recognition and error correction is so-called syndrome computation.

The syndrome S(y) of the received data word y is a column vector of length r. Only codewords are transmitted. If no errors have arisen during transmission, the received data word y is identical to the transmitted codeword c and the syndrome S(y) is zero. If one or more bits were corrupted (inverted) during transmission, the received data word y differs from the transmitted codeword c at the applicable locations, the so-called error locations. The syndrome S(y) is then almost always not equal to 0. An exception is provided by the rare cases in which the erroneous received data word y is itself again a (different) codeword (different than the transmitted codeword): Even then it holds that S(y)=0, permitting the incorrect interpretation that the data word y is error-free.

A syndrome of y is determined by the r x n parity check matrix H of the code. It holds that

S(y)=H·y^{T}.

The parity check matrix H of a linear code is not clearly determined. For each invertible r×r matrix J with r=n−k,

H′'²J−H

is also a parity check matrix of the code C. For this reason, the syndrome is only defined relative to a given parity check matrix H.

Although a linear code has numerous equivalent parity check matrices, codes for which an efficient error correction algorithm is known are predominantly used in practice. The error correction algorithm uses properties of a quite specific parity check matrix H, and the input it requires is the syndrome computed using this parity check matrix. From the point of view of implementation, the parity check matrix H of the code and therefore also the syndromes S(y) of vectors y comprising V=GF(2)ⁿ are thus clearly determined.

Furthermore, from the point of view of implementation, a linear code C is a structured vector space and an efficient method for error correction with a distinguished parity check matrix H for syndrome computation.

The code C preferably has the following main properties:
Main property 1:
   All error-free data words y are recognized as error-free.
Main property 2:
   All sufficiently small errors that have arisen during transmission are corrected. Here, “sufficiently small” means in particular that fewer than d/2 bit errors have arisen in the transmitted codeword, d being the minimum distance of the code.

If an error that is no longer sufficiently small arises during the transmission of a codeword, i.e. more than d/2 bit errors have arisen, a distinction can be drawn between the following cases:
Case A:
   The received data word is recognized as erroneous (and uncorrectable).
Case B:
   The erroneous received data word is incorrectly classified as error-free because its syndrome is zero. (The transmitted codeword has been corrupted into a different codeword; a codeword is recognized, and therefore the syndrome is equal to zero, but it is the incorrect codeword.)
Case C:
   The syndrome is not equal to zero; the erroneous received data word is routed to the error correction algorithm, which constructs an incorrect error vector therefrom, however. In this case, a so-called decoding error occurs.

The uncorrectable data words of a code can thus be divided into two classes:
Into class I of data words identifiable as erroneous (case A).
Into class II of data words that are incorrect but are either not recognized as erroneous (case B) or are recognized as erroneous but are transformed into an incorrect codeword (different than the correct codeword) in the course of “error correction” (case C).

The relative sizes of class I and class II together determine the secondary property of the code: Class I is meant to be as large as possible and class II is meant to be as small as possible: As many errors as possible are then recognized and as few errors as possible remain undetected.

### Reduced Syndrome Computation

Errors arise relatively rarely during a typical data transmission. That means that the syndromes of the received data words are usually zero. Error correction is thus unnecessary. In this case, syndrome computation is performed always, error correction rarely. The average computing time and the power consumption of decoding is thus determined substantially by the computing time or power consumption for syndrome computation.

Illustrative embodiments described herein are thus aimed at performing syndrome computation for the received data words not in full but rather only as far as a specific part.

Such partial determination of the syndrome can suffice to detect possible errors in the received message and by and large to reduce computation complexity (computing power, time, power consumption) for syndrome computation and therefore for decoding.

By way of example, a shortened syndrome can be determined:
if the shortened syndrome is zero, the received message is classified as error-free.
if the shortened syndrome is not equal to zero (in which case the full syndrome is naturally also not equal to zero), an error has arisen. Only in this case is the still missing part of the full syndrome computed and error correction carried out by means of the full syndrome.

Linear codes for which main properties 1 and 2 are fully maintained for a (suitable) shortened syndrome computation can preferably be used. The shortened syndrome computation affects only the secondary properties of the code in the case of these codes.

### Suitable Codes for a Shortened Syndrome Computation

Codes for a shortened syndrome computation preferably satisfy the following condition: The linear (n, k, d) code C has an error correction algorithm with an associated parity check matrix H that contains a submatrix H₁, the null space of which defines a (weaker) code C₁, and the code C₁ can already recognize all errors that the original code C can and is meant to correct.

For the purposes of illustration, the code C is also referred to as the strong code and the code C₁ is also referred to as the weak code below.

From the above condition there follows a required and adequate condition for the minimum distances of the two codes C and C₁: If the (strong) code C has the minimum distance

$$d = 2 t + 1 or d = 2 t + 2 ,$$

then the (weak) code C₁ has at least the minimum distance

$${d}_{1} = t + 1.$$

In order for the (strong) code C to be able to correct up to t-bit errors, the (weak) code C₁ must be able to recognize at least up to t-bit errors.

The power saving is greatest when the (weak) code C₁ has precisely the minimum distance d₁=t+1. This case is an optimum for a suitable code C with minimum length n.

Furthermore, it is proposed that linear codes C for which a (weak) code C₁ with the minimum distance d₁=t+1 exists according to the above description be used for error correction.

Various approaches are presented below.

Method 1: C and C₁ have the same length

The (weak) error-recognizing code C₁ and the original error-correcting (strong) code C have the same length n.

As a vector space, the code C₁ contains the code C as a subspace. The shortened syndrome computation is then the regular syndrome computation in the weakened code C₁. This means that the code C₁ does not have to be implemented separately; it is part of the syndrome computation for the code C.

This method can preferably be used when the aim is to correct, or to verify as error-free, all coordinates of the received message word. If only parts of a received message word are of interest, it suffices to correct the coordinates they contain (this is explained in more detail in method 2 below).

Method 1 is suitable in particular for codes with noncanonical parity check matrices. Linear codes with efficient error correction algorithms frequently have noncanonical parity check matrices for syndrome computation: The input required by the error correction algorithm is then syndromes that need to be computed using a specific noncanonical parity check matrix.

Codes with canonical parity check matrices are described under method 2 below.

### EXAMPLE 1

A double-error-correcting BCH code C of length n=15 is considered by way of illustration. This code has the dimension k=7 and the minimum distance d=5. The parity check matrix H is provided by:

$$H = [ \begin{matrix}1 & 0 & 0 & 0 & 1 & 0 & 0 & 1 & 1 & 0 & 1 & 0 & 1 & 1 & 1 \\ 0 & 1 & 0 & 0 & 1 & 1 & 0 & 1 & 0 & 1 & 1 & 1 & 1 & 0 & 0 \\ 0 & 0 & 1 & 0 & 0 & 1 & 1 & 0 & 1 & 0 & 1 & 1 & 1 & 1 & 0 \\ 0 & 0 & 0 & 1 & 0 & 0 & 1 & 1 & 0 & 1 & 0 & 1 & 1 & 1 & 1 \\ 1 & 0 & 0 & 0 & 1 & 1 & 0 & 0 & 0 & 1 & 1 & 0 & 0 & 0 & 1 \\ 0 & 0 & 0 & 1 & 1 & 0 & 0 & 0 & 1 & 1 & 0 & 0 & 0 & 1 & 1 \\ 0 & 0 & 1 & 0 & 1 & 0 & 0 & 1 & 0 & 1 & 0 & 0 & 1 & 0 & 1 \\ 0 & 1 & 1 & 1 & 1 & 0 & 1 & 1 & 1 & 1 & 0 & 1 & 1 & 1 & 1\end{matrix} ]$$

The codewords c E C and the incoming message words y have the length 15. The syndrome S(y) is a column vector of length 8.

The first four rows of the parity check matrix H yield a 4×15 submatrix H1:

$$H 1 = [ \begin{matrix}1 & 0 & 0 & 0 & 1 & 0 & 0 & 1 & 1 & 0 & 1 & 0 & 1 & 1 & 1 \\ 0 & 1 & 0 & 0 & 1 & 1 & 0 & 1 & 0 & 1 & 1 & 1 & 1 & 0 & 0 \\ 0 & 0 & 1 & 0 & 0 & 1 & 1 & 0 & 1 & 0 & 1 & 1 & 1 & 1 & 0 \\ 0 & 0 & 0 & 1 & 0 & 0 & 1 & 1 & 0 & 1 & 0 & 1 & 1 & 1 & 1\end{matrix} ]$$

The null space C1 of the matrix H1 is a linear (15, 11, 3) code. As the code C1 has the minimum distance d₁=3, it can recognize all 1-bit errors and all 2-bit errors. The original BCH code C has the minimum distance d=5 and can therefore correct all 1-bit errors and all 2-bit errors.

The (long) syndrome S(y) of y in the BCH code C is provided by:

$$S ( y ) = H \cdot {y}^{T} = {( s 1 , s 2 , s 3 , s 4 , s 5 , s 6 , s 7 , s 8 )}^{T}$$

The (shorter) syndrome s(y) of y in the code C₁ is the first half of the long syndrome S(y) and therefore provided by:

$$s ( y ) = H 1 \cdot {y}^{T} = {( s 1 , s 2 , s 3 , s 4 )}^{T}$$

If the incoming data word y is erroneous, both syndromes are zero.

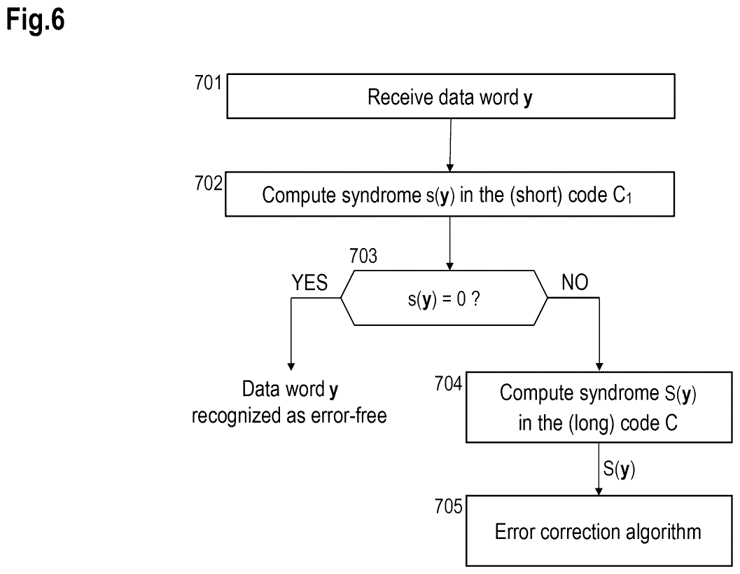

FIG. 6 shows an illustrative flowchart for reduced syndrome computation. In a step 701, the data word y is received. In a subsequent step 702, only the (short) syndrome s(y) is initially computed. In a step 703, it is then checked whether the short syndrome s(y) is equal to zero. If s(y)=0, the data word y is already classified as error-free. If, on the other hand, s(y)≠0 is true for the short syndrome, the process branches to a step 704 and the long syndrome S(y) is computed. As the short syndrome s(y) is already the first half of the long syndrome S(y), only the second half of S(y) now needs to be computed in this case. The long syndrome S(y) is used as the input into the error correction algorithm (step 705). If there is a 1-bit error or a 2-bit error, it can be corrected.

This approach permits a clear power saving for the hardware implementation of the associated error correction method of the code: As a large proportion of the received data words y is error-free, only the small syndrome s(y) is computed for said data words. Since only half the circuit for syndrome computation is active for this, the power saving during decoding is approximately 50%.

It will be noted in this context that the two codes (15, 7, 5) and (15, 11, 3) used in the example have the shortest possible length for the given parameters. The error recognition property is provided for 11 data positions of the small code, the error correction property being needed for only 7 data positions of the large code.

In example 1, the small syndrome is computed on the basis of the first four rows of the matrix H. It is also possible to use a different selection of four rows. If for example the first, fifth, sixth and seventh rows of the matrix H are used, the vector (s1, s5, s6, s7) is obtained for the short syndrome. The 4×15 submatrix of the matrix H, which consists of the aforementioned four rows, has three empty columns, specifically columns 2, 7 and 12. The underlying code C₁ for the error recognition in this case is therefore a linear (12, 8, 3) code, the parity check matrix H1′ of which is provided by

$$H {1}^{′} = [ \begin{matrix}1 & 0 & 0 & 1 & 0 & 1 & 1 & 0 & 1 & 1 & 1 & 1 \\ 1 & 0 & 0 & 1 & 1 & 0 & 0 & 1 & 1 & 0 & 0 & 1 \\ 0 & 0 & 1 & 1 & 0 & 0 & 1 & 1 & 0 & 0 & 1 & 1 \\ 0 & 1 & 0 & 1 & 0 & 1 & 0 & 1 & 0 & 1 & 0 & 1\end{matrix} ]$$

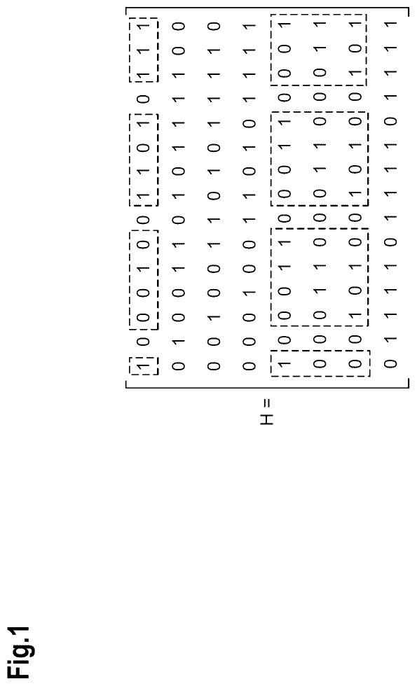

FIG. 1 illustrates how the parity check matrix H1′ is obtained from the matrix H according to the description above. The parity check matrix H1′, identified by the regions marked by dashed lines, is a submatrix of the matrix H.

The new, associated code C₁ is not yet optimum: This would require a (11, 7, 3) code, the 4 x 11 parity check matrix of which does not appear as a submatrix in the matrix H, however.

If the new shortened syndrome (s1, s5, s6, s7)^{T} is not equal to zero, the remaining syndrome coordinates s2, s3, s4 and s8 are computed using the matrix H. The full syndrome S(y)=(s1, s2, s3, s4, s5, s6, s7, s8)^{T} forms the input for the error correction algorithm.

If the shortened syndrome (s1, s5, s6, s7)^{T} has the value zero, this means (assuming that no more than a 2-bit error has arisen) that the coordinates

y1,y3,y4,y5,y6;y8,y9,y10,y11,y13,y14 and y15

are error-free. To determine the entire codeword, the still missing coordinates y2, y7 and y12 are determined from the 12 coordinates that are already known. The fully transmitted codeword is then available.

This approach is correct even if transmission errors should have arisen at location 2, 7 or 12.

As already outlined, the main properties of the code are maintained in the power-saving operating mode (with the shortened syndrome computation). The approach proposed here merely influences the secondary properties of the code such that the shortened syndrome computation increases the number of possible decoding errors of undecodable received messages (above case A becomes case B).

For the purposes of illustration, it is assumed by way of example that a 3-bit error arises in a BCH codeword. As the BCH code C in example 1 has the minimum distance d=5, 3-bit errors can no longer be corrected. As the codeword length is n=15,

$$( \begin{matrix}15 \\ 3\end{matrix} ) = \frac{15 !}{3 ! \cdot ( 15 - 3 ) !} = 455$$

various options exist by and large for a 3-bit error. Of these 455 possible error patterns, 275 data words containing a 3-bit error are recognized by the error correction algorithm as erroneous and undecodable. Referring to the classes introduced above, this means that class I (case A) contains 275 elements. The remaining 180 data words containing a 3-bit error are incorrectly classified as decodable and converted into a different BCH codeword by the error correction algorithm (case C). Class II therefore contains 180 elements (case B does not arise in this example because the syndrome of a codeword containing a 3-bit error in a code with the minimum distance d=5 cannot be zero).

The approach proposed here with the shortened syndrome computation results in: The (short) code C₁ is a linear (15, 11, 3) code with 2¹¹=2048 codewords. Of these, 35 codewords have the Hamming weight 3. If, during transmission, a 3-bit error arises in the transmitted BCH codeword at precisely the locations at which there is a 1 in one of the aforementioned 35 codewords, the short syndrome s(y) of the received data word y has the value zero and the received message y is classified as error-free even though it contains a 3-bit error. This means that the originally empty case B now contains 35 elements and case A now contains only 240 elements. Case C contains 180 elements in both cases, i.e. for shortened and full syndrome computation.

If the long syndrome S(y) had instead been computed for the message y, it would have been found to be different than zero. The value S(y) would have been input into the error correction algorithm, and the error correction algorithm would have classified y as erroneous and uncorrectable.

In summary, the following can be stated: With the conventional approach, 275 of the possible 455 patterns for 3-bit errors are recognized. In the power-saving mode, only 240 of all 3-bit errors are recognized.

The difference in the secondary properties of the code plays a minor role in practical applications, however, as the occurrence of uncorrectable errors is very unlikely. Let us assume that the probability of a bit error at any position during data transmission is p=0.002 and the code has the length n=15. In this case, 97% of the transmitted codewords arrive without error. Furthermore, a 1-bit error occurs for 2.91% of the transmissions and a 2-bit error occurs for 0.04% of the transmissions, and a 3-bit error arises for only one of 2.8-10′ transmissions.

### Systematic Codes:

Let the code C be a linear (n, k, d) code. In a codeword c E C, k coordinates can be freely selected. The remaining n-k coordinates of the codeword are then linear combinations (i.e. XOR sums for codes over GF(2)) of the k freely selectable coordinates. In the case of a so-called systematic code, the k freely selected coordinates arise explicitly in the codeword.

The codewords c in a systematic linear (n, k, d) code frequently have the form

$$c = ( {b}_{1} , … , {b}_{k} , {c}_{k + 1} , … , {c}_{n} ) .$$

This means that the k freely selectable message bits b₁, . . . , bₖ are extended by r=n−k redundancy bits cₖ₊₁, . . . , cₙ.

In numerous applications, only the transmitted message bits are of interest. The redundancy bits merely serve the purpose of being able to recognize and correct possible transmission errors in the message bits. The decoding aim is already deemed to have been achieved if the message bits have been verified as free from error or any erroneous message bits that have arisen have been corrected. Erroneous redundancy bits are not corrected.

The aforementioned main properties 1 and 2 can therefore be modified as follows:
Main property 1:
   The error-free message bits in a received data word y are recognized as error-free. It must be possible to recognize that the message bits are correct; the other bits are of minor interest. If they are needed, they can be computed deterministically from the message bits.
Main property 2:
   All sufficiently small errors in the message bits that have arisen during transmission are corrected. Here, “sufficiently small” means in particular that fewer than d/2 bit errors have arisen in the transmitted codeword, d being the minimum distance of the code.

The parity check matrix H of a systematic (n, k, d) code C has the form

H=(A,I),

where A is an r×k matrix and I is the r x r unity matrix, with r=n−k.

### EXAMPLE 2

The parity check matrix

$$H 2 = [ \begin{matrix}1 & 1 & 1 & 0 & 1 & 0 & 0 & 0 \\ 1 & 1 & 0 & 1 & 0 & 1 & 0 & 0 \\ 1 & 0 & 1 & 1 & 0 & 0 & 1 & 0 \\ 0 & 1 & 1 & 1 & 0 & 0 & 0 & 1\end{matrix} ]$$

defines a systematic linear (8, 4, 4) code (a Reed-Muller code). Four redundancy bits c₅, . . . c₈ are appended to four message bits b₁, . . . , b₄. For any row vector

c=(b₁,b₂,b₃,b₄,c₅,c₆,c₇,c₈),

the redundancy bits are obtained from the message bits as follows: It holds that: c is a codeword precisely when

$$H \cdot {c}^{T} = 0 ,$$

that is to say precisely when the following applies:

b₁⊕b₂⊕b₃⊕c₅=0,

b₁⊕b₂⊕b₄c₆=0,

b₁⊕b₃⊕b₄⊕c₇=0

b₂⊕b₃⊕b₄⊕c₈=0.

There follows:

c₅=b₁⊕b₂⊕b₃,

c₆=b₁⊕b₂⊕b₄,

c₇=b₁⊕b₃⊕b₄and

c₈=b₂⊕b₃⊕b₄.

### Method 2:

The (weak) error-recognizing code C₁ and the original (strong) error-correcting (n, k, d) code C have the same dimension k, but different lengths: The code C₁ is an (n₁, k, d₁) code with n₁<n and d₁=t+1 if the code C has the minimum distance d=2t+1 or d=2t+2 for the error correction.

The codes C₁ and C thus contain identical numbers of (specifically precisely 2^{k}) codewords.

The codewords of the code C₁ are shortened codewords of C. It is assumed that a shortened codeword of a systematic code C₁ consists of the first n₁ coordinates of the associated codeword of the systematic code C.

If a data word y is received, the syndrome is initially computed (as in method 1) in the code C₁. If this (short) syndrome has the value zero, the k message bits of the n-bit data word are classified as error-free and the decoding of the data is (successfully) terminated. The coordinates yᵢ with n₁<i≤n are thus not included in the syndrome computation, it being entirely possible for at least one of these coordinates yᵢ to be erroneous. As these coordinates are (merely) redundancy bits, however, error recognition or error correction is of minor interest for these coordinates yᵢ. The insight that the message bits

y₁=b₁, . . . ,yₖ=bₖ

according to the code C₁ are erroneous is sufficient for the decoding. If an application also requires the remaining (error-free) redundancy bits, these can be determined from the message bits.

If the syndrome computed in the code C₁ is not equal to zero, the received data word y is erroneous. The (strong) code C is now used to compute the long syndrome and to perform the error correction in the code C. The long syndrome is actually an extension of the short syndrome, and it is thus possible to use the already computed coordinates of the short syndrome.

### EXAMPLE 3

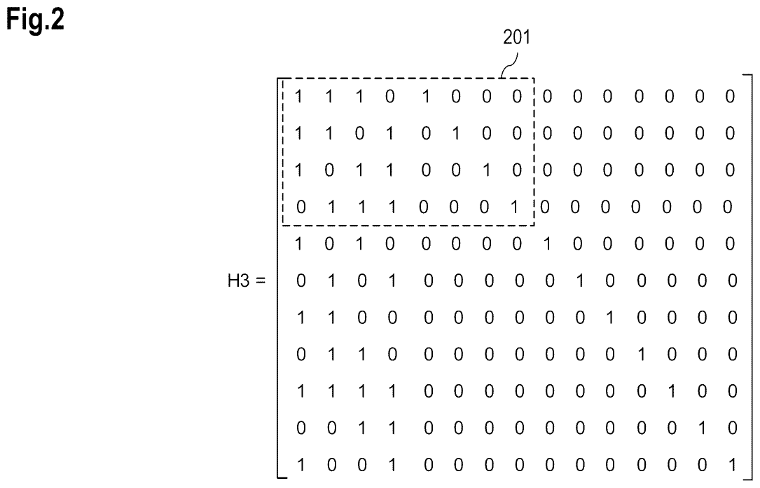

FIG. 2 shows an illustrative parity check matrix H3 with a region 201 marked by dashed lines that is referred to as the submatrix of the parity check matrix H3.

The parity check matrix H3 defines a linear systematic (15, 4, 8) code with the dimension k=4. This code can thus be used to protect 4 message bits from error. 11 redundancy bits are appended to the 4 message bits, with the result that a codeword of length n=15 is obtained. The code has the minimum distance d=8. All 1-bit errors, all 2-bit errors and all 3-bit errors in the 15-bit codeword can therefore be corrected.

The 4×8 submatrix of the parity check matrix H3 is identical to the matrix H2 from example 2. The submatrix defines a linear systematic (8, 4, 4) code C₁ with the minimum distance d₁=4. The code C₁ can thus be used to recognize all 1-bit errors, all 2-bit errors and all 3-bit errors. The weak code C1 can therefore recognize precisely the errors that the strong code C can correct.

Let y=(y₁, . . . , y₁₅) be the received data word. For the shortened vector

ŷ=(yᵢ, . . . y₈),

the shortened syndrome

$$\hat{s} = H 2 \cdot {\hat{y}}^{T}$$

is computed. The shortened syndrome ŝ has the length 4. If the shortened syndrome § has the value zero, the eight message bits in ŷ=(y₁, . . . , y₈) are error-free, i.e. no more than one 3-bit error has arisen in the entire data word y=(y₁, . . . , y₁₅). If the short syndrome § is not equal to zero, the 11-bit syndrome

$$s = H 3 \cdot {y}^{T}$$

is computed in the code C for the entire data word y=(y₁, . . . , y₁₅). It is enough here to compute the remaining 7 syndrome coordinates; the first four syndrome coordinates are identical to the coordinates of the shortened syndrome s.

The long syndrome s is input into the error correction algorithm and all existing errors in the data word y=(y₁, . . . , y₁₅) are corrected. In particular, any errors in the four message bits

b₁=y₁,b₂=y₂,b₃=y₃and b₄=y₄

are corrected.

It will be noted that the codes C (15, 4, 8) and C₁ (8, 4, 4) used in this example have the shortest possible length for the given dimension and minimum distance and have therefore been chosen in optimum fashion.

### Other Embodiments and Advantages

The section above has dealt with the following problem: A strong (or long or large) code C is provided for error correction. A weak (or short or small) code C₁ is introduced for error recognition. The code parameters (length, dimension, minimum distance) of the two codes are chosen such that the weak code C₁ can recognize all errors that the strong code C can correct.

In this context, it will be noted that the attributes “large” and “small” relate to the code parameters and not to the size of the sets C and C₁. By way of example, the weak code C₁ can comprise more codewords than the strong code C.

If the parity check matrix of the code C₁ is a submatrix of the parity check matrix of the code C, the code C₁ is “contained” in the code C.

Another reason for introducing and using the error recognition code C₁ is that in most cases the received data words are error-free, or that single errors arise far more frequently than multiple errors. As the number of errors per data word increases, the probability of occurrence of said errors falls. It is thus sufficient, for the majority of cases, to carry out error recognition using the weak code C₁, which has a shorter syndrome, in order to save power and/or computing time.

Variant: More than Two Codes

The approach described here can be extended to more than two codes. By way of example, it is possible to use three (or more) codes “contained” in one another.

The strong code C is used to correct errors that arise rarely. The weak code C₁ is used to establish whether or not the received data word contains errors (in most cases it is error-free, and so by and large fewer syndrome computations arise during decoding). A median code can be used to correct small errors (e.g. all 1-bit errors).

As already explained, no errors arise in most cases. Furthermore, single errors arise far more frequently than multiple errors. In the example above, it was explained that 1-bit errors arise approximately 73 times more frequently than 2-bit errors or 3-bit errors.

### EXAMPLE 4

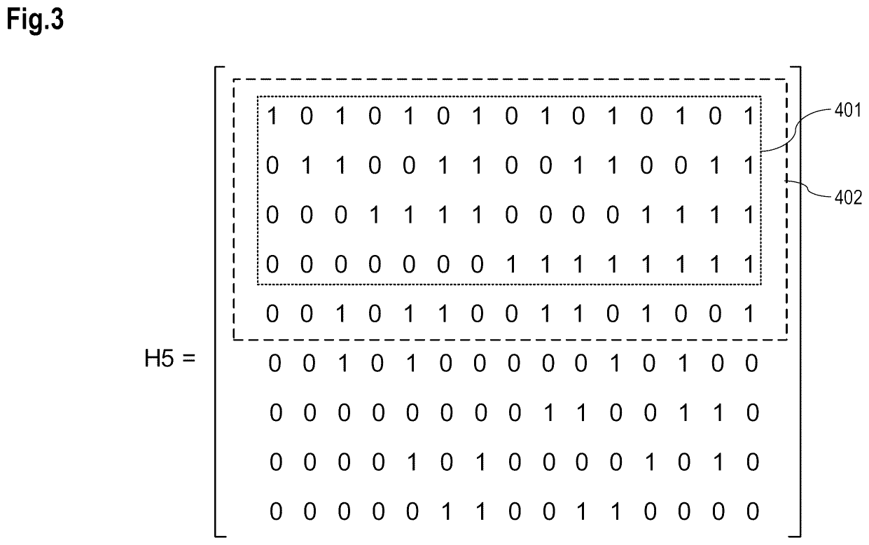

FIG. 3 shows an illustrative parity check matrix H5. The null space of the code C of the matrix H5 is a linear (15, 6, 6) code, that is to say a (nonsystematic) code with the length n=15, the dimension k=6 and the minimum distance d=6. This code C can be used to correct all 1-bit errors and all 2-bit errors.

FIG. 3 also shows a 4×15 submatrix 401 that determines a linear (15, 11, 3) code C₁. The code C₁ is identical to the Hamming code of length 15. This code C₁ can be used to recognize all 1-bit errors and all 2-bit errors, using a 4-bit syndrome vector

s_{C1}=(s₁,s₂,s₃,s₄)^{T}

FIG. 3 also shows a 5×15 submatrix 402 that defines a linear (15, 10, 4) code C₂. This code C₂ can be used to correct all 1-bit errors and to recognize all 2-bit errors, using a 5-bit syndrome vector

s_{C2}=(s_{C1};s₅)=(s₁,s₂,s₃,s₄,s₅)^{T}

The large code C can additionally also be used to correct all 2-bit errors, the input required by the error correction algorithm being the 9-bit syndrome

s=(s_{C2};s₆,s₇,s₈,s₉)^{T}=(s₁,s₂,s₃,s₄,s₅,s₆,s₇,s₈,s₉)^{T}

Three computation examples are described below to illustrate the manner of operation:

### EXAMPLE 4a

The received data word is

y=(001011110000001).

The syndrome si in the code C₁ is determined using the parity check matrix 401 as

s_{C1}=(0,0,0,0)^{T}

As the syndrome si is equal to zero, y is classified as error-free.

### EXAMPLE 4b

The received data word is

y=(111100000000100).

In the code C₁, the syndrome

$${s}_{C 1} = {( 1 , 0 , 0 , 1 )}^{T} \neq 0$$

is determined. As s₁ is not equal to zero, the data word y contains at least one error. The fifth row of the matrix H5 is used to determine the syndrome coordinate s₅ as s₅=1. The syndrome s_{C2} in the median code C₂ is thus provided by

s_{C2}=(1,0,0,1,1)^{T}

The rule for error correction in the code C₂ is: If the syndrome s_{C2} has an uneven Hamming weight, there is a 1-bit error. The position of the 1-bit error can be determined by interpreting the first 4 syndrome coordinates of s_{C2} as a binary representation of the error position. In the present case, the error location is the position

(1001)_{B}=9.

The corrected codeword is thus

c=(111100001000100).

### EXAMPLE 4c

The received data word is

y=(011101110000000).

The syndrome s_{C1} in the code C₁ is obtained as

$${s}_{C 1} = {( 0 , 0 , 1 , 1 )}^{T} \neq 0$$

The syndrome

s_{C2}=(0,0,1,1,0)^{T}

has an even Hamming weight. There is therefore not only a 1-bit error. The long syndrome

$$s = H 4 \cdot {y}^{T}$$

of the strong code C is thus computed. The first five syndrome coordinates are already known, the result being

s=(0,0,1,1,0,1,0,1,0)^{T}.

The long syndrome is input into the error correction algorithm. Said algorithm computes the positions of the 2-bit error that has arisen in approximately 20 steps. The error locations are 7 and 11. In this case, the corrected codeword is therefore

c=(011101010010000).

In example 4, the three interleaved codes had the same length n=15. In a subsequent example, the three codes have the same dimension k=4.

### EXAMPLE 5

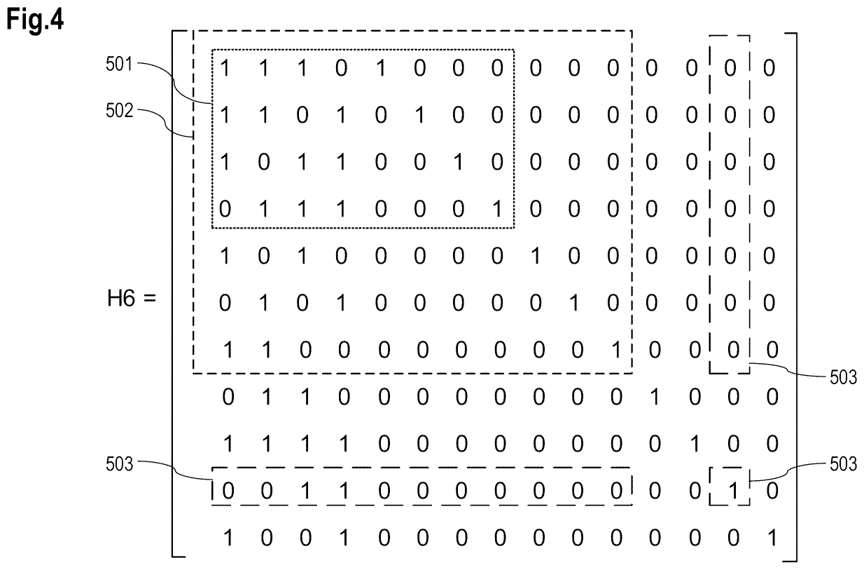

FIG. 4 shows an illustrative parity check matrix H6 of a systematic linear (15, 4, 8) code C. This code can be used to correct all 1-bit errors, all 2-bit errors and all 3-bit errors.

FIG. 4 also shows a 4×8 submatrix 501 that defines a linear (8, 4, 4) code C₀. As the code C₀ has the minimum distance 4, it is used to recognize all 1-bit errors, all 2-bit errors and all 3-bit errors. The syndrome of the code C₀ that needs to be computed for error recognition has the length 4 and is determined by

(s₁,s₂,s₃,s₄)^{T}

In this case, it will be noted that the code C₀ is used not to correct errors but rather only to recognize errors.

FIG. 4 also shows a 7×11 submatrix 502 that defines a linear (11, 4, 5) code C₁. The code C₁ is used to correct 1-bit errors, this being barely more complex than the syndrome computation itself on account of the special structure of the submatrix 502. The syndromes in the code C₁ have the length 7. The syndrome in the code C₁ is determined by

(s₁,s₂,s₃,s₄,s₅,s₆,s₇)^{T}

Furthermore, the matrix H6 contains a 8×12 submatrix that comprises the submatrix 502 and elements 503. This 8×12 submatrix defines a linear (12, 4, 6) code C₂. The code C₂ can be used to correct all 2-bit errors. The syndromes in the code C₂ have the length 8 and the form

(s₁,s₂,s₃,s₄,s₅,s₆,s₇,s₁₀)^{T}

Finally, the code C can also be used to correct all 3-bit errors using the 11-bit syndrome

$$s = H 6 \cdot {y}^{T} = {( {s}_{1} , {s}_{2} , {s}_{3} , {s}_{4} , {s}_{5} , {s}_{6} , {s}_{7} , {s}_{8} , {s}_{9} , {s}_{10} , {s}_{11} )}^{T} .$$

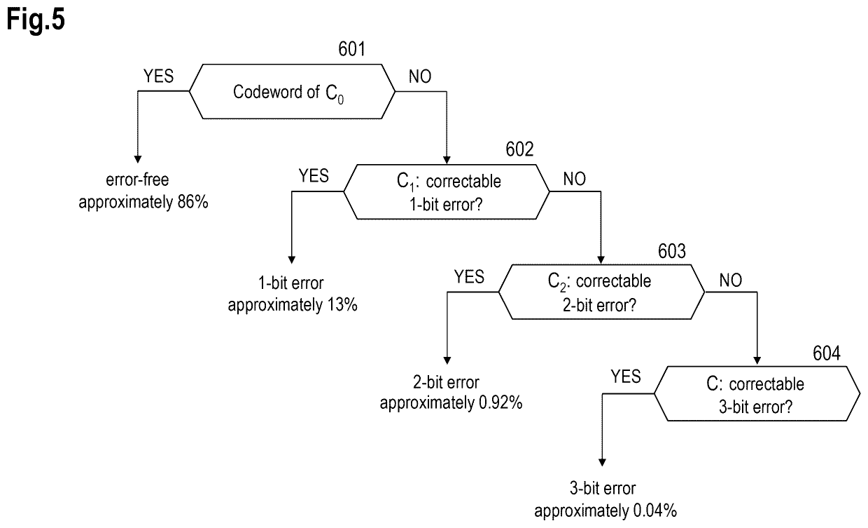

FIG. 5 shows a schematic diagram of the escalated syndrome computations according to example 5 above.

A step 601 comprises checking whether the syndrome of the code C₀ is error-free. If this is the case, the received data word is assumed to be error-free without further syndrome computation(s) and processed further.

If step 601 determined that there is at least one error, the process branches to a step 602. This step checks whether the code C1 and the associated syndrome result in there being a 1-bit error, and if necessary this 1-bit error is corrected. The corrected data word is processed further.

If step 602 results in there being no 1-bit error, the process branches to a step 603. The extended syndrome of the code C₂ is used to check whether there is a 2-bit error, and if necessary this 2-bit error is corrected. The corrected data word is processed further.

If step 603 results in there being no 2-bit error, the process branches to a step 604. The (full) syndrome of the code C can now be used to correct a 3-bit error. The corrected data word is processed further.

The probabilities indicated in FIG. 5 for the occurrence of data words recognized as error-free or for the occurrence of 1-bit errors, 2-bit errors and 3-bit errors can be understood by way of illustration, but shows that the probabilities of higher-order errors per data word significantly decrease. In this respect, it is advantageous that longer syndromes are computed correspondingly (more) rarely.

### Suitable Codes for a Shortened Syndrome Computation

An optimum binary (n, k, d) code C with minimum code length n for a given dimension k and a given minimum distance d is not clearly determined by these properties in general. By way of example, indication of the generator matrix of the code C is suitable for clearly describing said code. Many matrices that produce such a code C often exist for a parameter set (n, k, d).

The set of these matrices can be used to define equivalence classes: For example, the properties of a code do not change when rows or columns of its generator matrix are permuted. For codes in non-systematic representation, the equivalence relation can also be extended to row and column operations (that is to say linear combinations of rows or columns) in addition to the row and column permutations.

To find a sufficiently strong code C with a matching weak code C₁, it is possible to iterate for example over a representative system of its equivalence classes and, for a (each) representative, to test whether said representative contains a suitable subcode. In practical application, this method works predominantly for short code lengths, both because determining a representative system of non-equivalent codes is mathematically complex and because the number of cases to be tested (and therefore the size of the search space) grows exponentially.

Alternatively, the following heuristic method can be used to find suitable codes: Proceeding from a (n, k, d) code of extremely short code length, which code is provided by its generator matrix, for example, transformations can be carried out for small subregions of the matrix (for example changing the bits of few entries). Each transformation is followed by testing to ascertain firstly whether the resulting matrix still produces a (n, k, d) code and secondly whether the matrix contains the sought subcode as a partial matrix. If both conditions are met, the representation of a suitable code was found. Otherwise, the method is iterated and for example a systematically next transformation is applied to the original code matrix.

Although the invention has been illustrated and described more thoroughly in detail by way of the at least one exemplary embodiment shown, the invention is not restricted thereto and other variations can be derived therefrom by a person skilled in the art without departing from the scope of protection of the invention.

1. A method for processing a data word,
in which a data word is received,
in which a first syndrome of a first code is determined, the first syndrome having components, and
in which a second syndrome of a second code is determined when the syndrome of the first code recognizes an error, the second syndrome comprising the components of the first syndrome.

2. The method of claim 1, in which the received data word is recognized as error-free if no errors were recognized on the basis of the first syndrome of the first code.

3. The method of claim 1, in which if an error was recognized on the basis of the first syndrome of the first code, this error is corrected by means of the second code.

4. The method of claim 1, in which the first code can recognize at least t bit errors and the second code can correct t bit errors.

5. The method of claim 4, in which the first code has a minimum distance of t+1.

6. The method of claim 1, in which the first code and/or the second code is a linear code.

7. The method of claim 1, in which the data word has data bits or data bits and redundancy bits.

8. The method of claim 7, in which if an error was recognized on the basis of the first syndrome of the first code, this error is corrected by means of the second code only in the data bits.

9. A method for processing a data word,
in which a data word is received,
in which a first syndrome of a first code is determined, and
in which a syndrome of another code is determined when the syndrome of the first code recognizes an error, and an error correction is carried out on the basis of the syndrome of the other code, or, if error correction on the basis of the other code is not possible, a second syndrome of a second code is determined,
wherein the other code is contained in the second code, and the first code is contained in the other code.

10. The method of claim 9, in which if an error that cannot be corrected on the basis of the other code was recognized on the basis of the other syndrome of the other code, this error is corrected by means of the second code.

11. A device for processing a data word, configured to carry out the steps of the method according to claim 1.

12. A computer program product that is directly loadable into a memory of a digital computer, comprising program code parts configured to carry out steps of the method of claim 1.
